(19) United States
(12) Patent Application Publication
(10) Pub. No.: US 2009/0073672 A1
(43) Pub. Date: Mar. 19, 2009

(54) ELECTROMAGNETIC SHIELD AND ELECTRONIC DEVICE USING THE SAME

(75) Inventors: CHUNG-YUAN CHEN, Tu-Cheng (TW); SHIH-FANG WONG, Tu-Cheng (TW); WU-YUNG CHEN, Tu-Cheng (TW); CHENG-YI CHAO, Tu-Cheng (TW); CHIH-CHIEH HUANG, Tu-Cheng (TW); JING LIU, Shenzhen City (CN); TING-JIAN ZOU, Shenzhen City (CN); YI-TAO HUA, Shenzhen City (CN); JI-PING WU, Shenzhen City (CN); KOK-KAN CHAN, Shenzhen City (CN)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/138,436

(22) Filed: Jun. 13, 2008

(30) Foreign Application Priority Data
Sep. 14, 2007 (CN) 200710201710.0

(51) Int. Cl. H05K 9/00

(52) U.S. Cl. 361/818; 174/351

(57) ABSTRACT

An electromagnetic shield includes a conductive foam, a plurality of adhesive tapes attached to a side of the conductive foam. The adhesive tapes are separated from each other. An electronic device using the electromagnetic shield to block electromagnetic energy from inner component or outer component is also provided.

### BACKGROUND

1. Field of the Invention

The present invention generally relates to electromagnetic interferences, and particularly to an electromagnetic shield for an electronic device.

2. Description of Related Art

Electronic devices radiate and may also be affected by electromagnetic waves in their surrounding environment. Therefore, electronic devices adopt electromagnetic shields to block electromagnetic waves from radiating out of and into the electronic devices from outside sources. Typically, conductive foam is commonly used as a screen to block the electromagnetic waves.

Referring to FIG. 10, an electromagnetic shield consists of a conductive foam 1 and an adhesive tape 2. The adhesive tape 2 is also conductive and attached to one side of the conductive foam 1. In practice, the electromagnetic shield is fixed appropriately on the electronic device, such as peripheral places around circuit modules or I/O ports, via the adhesive tape 2. The electromagnetic shield not only blocks the electromagnetic energy, but also conducts static electricity from the circuit modules or the I/O ports to outside of the shield.

However, a resistivity of the adhesive tape 2 is higher than that of the conductive foam 1, as a result, the electromagnetic shield has poor electrical conductivity. Therefore, the electromagnetic shield has a low efficiency in blocking the electromagnetic energy due to the electrically poor conductivity.

Therefore, improvements for the electromagnetic shield are needed in the industry to address the aforementioned deficiency.

### SUMMARY

An electromagnetic shield includes a conductive foam, a plurality of adhesive tapes attached to a side of the conductive foam. The adhesive tapes are separated from each other. An electronic device using the electromagnetic shield to block electromagnetic energy from inner component or outer component is also provided.

Other advantages and novel features of the present invention will become more apparent from the following detailed description of preferred embodiment when taken in conjunction with the accompanying drawings.

### BRIEF DESCRIPTION OF THE DRAWINGS

FIG. 1 is a cross-sectional view of an electromagnetic shield in accordance with a first exemplary embodiment.

FIG. 2 is a bottom plan view of the electromagnetic shield of FIG. 1.

FIG. 3 is a bottom plan view of an electromagnetic shield in accordance with a second exemplary embodiment.

FIG. 4 is a bottom plan view of an electromagnetic shield in accordance with a third exemplary embodiment.

FIG. 5 is a disassembled schematic diagram showing a notebook computer using the electromagnetic shield of FIG. 1, the electromagnetic shield disposed under a mainboard of the notebook computer.

FIG. 6 is an assembled schematic diagram showing the notebook computer of FIG. 5.

FIG. 7 is a disassembled schematic diagram showing the notebook computer using the electromagnetic shield of FIG. 1, the electromagnetic shield disposed between a connector and the notebook computer.

FIG. 8 is an assembled schematic diagram showing the notebook computer of FIG. 7.

FIG. 9 is cross-sectional view of the notebook computer along a line XI-XI in FIG. 8.

FIG. 10 is a cross-sectional view of a conventional electromagnetic shield.

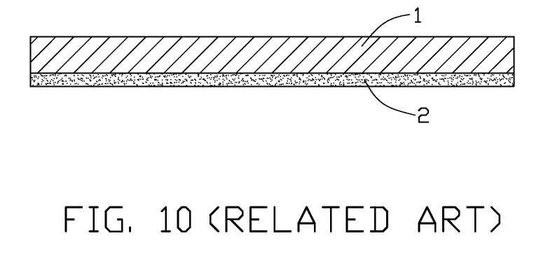

### DETAILED DESCRIPTION

Reference will now be made to the drawings to describe a preferred embodiment of the present electromagnetic shield, and a preferred embodiment of the present electronic device.

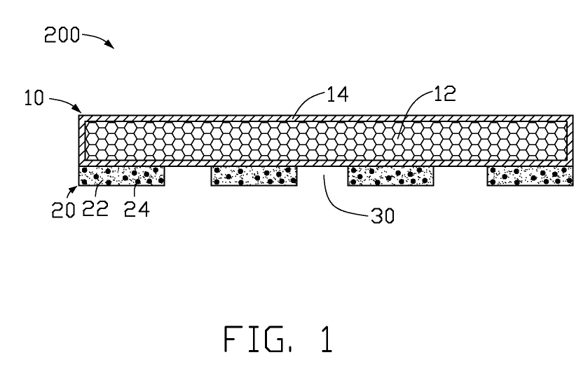

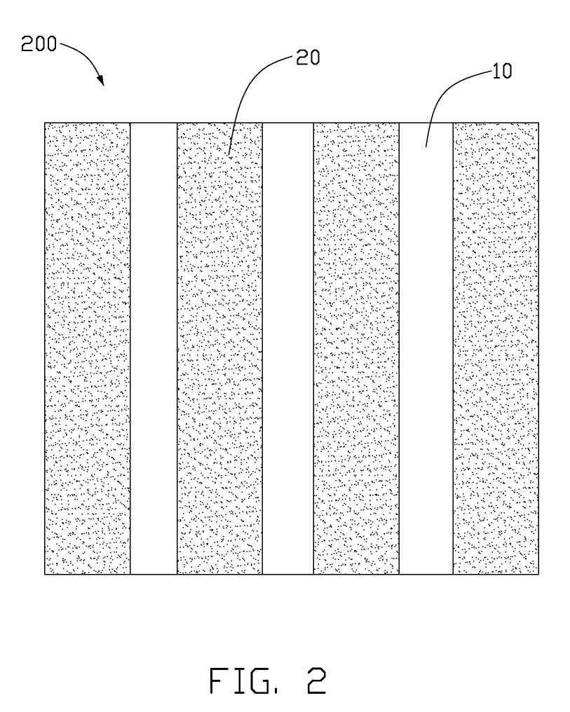

Referring to FIGS. 1-2, an electromagnetic shield 200 in accordance with a first embodiment is illustrated. The electromagnetic shield 200 includes a conductive foam 10 and a plurality of adhesive tapes 20. The adhesive tapes 20 are attached to a side of the conductive foam 10, and are aligned and separated from each other at a uniform distance. A plurality of gaps 30 is defined between the adhesive tapes 20.

The conductive foam 10 includes a foam 12 packed in a conductive coat 14. The conductive coat 14 is made of metallic foils, such as aluminum foil, silver foil, and so on. The foam 12 and the conductive coat 14 cooperatively provide flexibility and electrical conductivity.

Each adhesive tape 20 is an electric bond, such as electric glue, including a bond body 22 and metallic grains 24 dispersed in the bond body 22. The bond body 22 is made of adhesive materials such as adhesive resin. The metallic grains 24 are made of silver, copper, etc. When the adhesive tape 20 is pressed, the metallic grains 24 becomes in contact with each other. The electric conductivity of the adhesive tape 20 depends on the metallic grains 24 contacting each other.

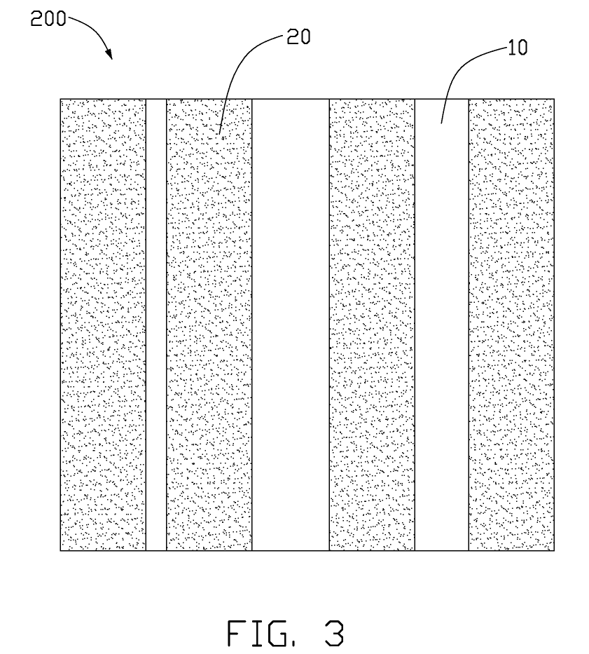

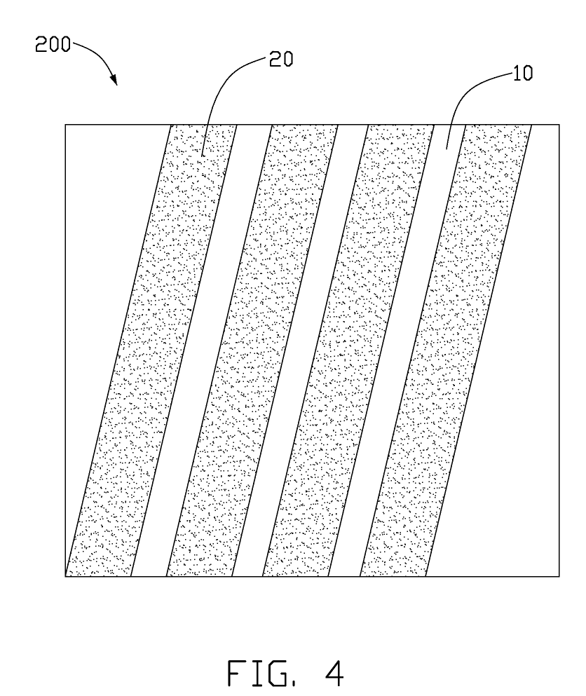

Referring to FIG. 3, in another embodiment, the adhesive tapes 20 are separated from each other at various distances on the conductive foam 10. Referring to FIG. 4, the adhesive tapes 20 can also be obliquely aligned on the conductive foam 10 with respect to an edge of the conductive foam 10 and separated at a uniform distance. Moreover, the adhesive tapes 20 can also be aligned in other forms as long as gaps are defined between the adhesive tapes 20.

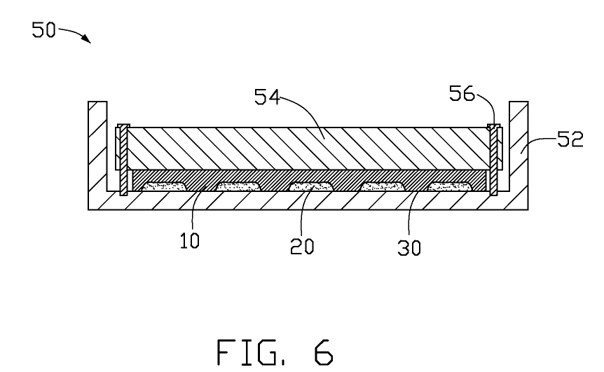

When the electromagnetic shield 200 is fixed into a position in an electronic device, the adhesive tapes 20 attaches the conductive foam 10 to the position in the electronic device, the conductive foam 10 partially deforms and fills the gaps 30 between the adhesive tapes 20. Thereby, the conductive foam 10 is in direct contact with the position. Therefore, an electric conductivity of the electromagnetic shield 200 is improved, and the electromagnetic shield 200 obtains a comparative shielding efficiency (see FIG. 6).

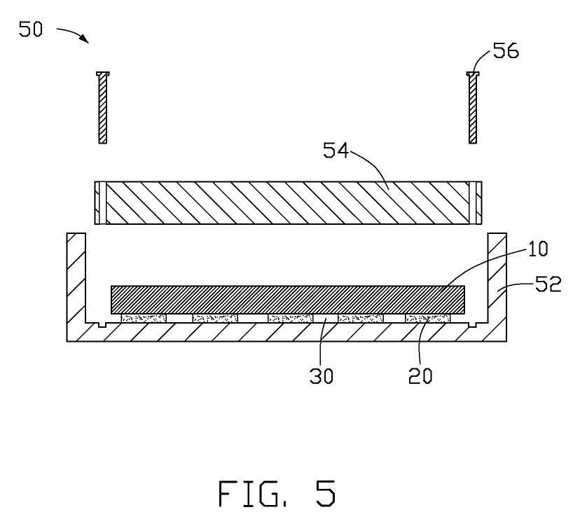

The electromagnetic shield 200 can be widely used in various electronic devices. For example, also referring to FIGS. 5-6, the electromagnetic shield 200 is used to block electromagnetic energy and conduct static electricity in a notebook computer 50. The notebook computer 50 includes a housing 52 and a mainboard 54. The mainboard 54 is attached onto the housing 52 via screws 56. The electromagnetic shield 200 is fixed between the housing 52 and the mainboard 54.

In assembly, the adhesive tapes 20 attaches to the housing 52, and the mainboard 54 is disposed on the conductive foam 10. The screws 56 pass through the mainboard 54 and fasten the mainboard 54 tightly onto the housing 52. In this manner, the conductive foam 10 is pressed by the mainboard 54 toward the housing 52. Consequently, the conductive foam 10 partially deforms and fills the gaps 30 between the adhesive tapes 20. Thereby, the conductive foam 10 is in direct contact with the housing 52. Therefore, static electricity can be conducted from the mainboard 54 to the housing 52, and electromagnetic energy can be blocked from interfering with the circuitry of the mainboard 54.

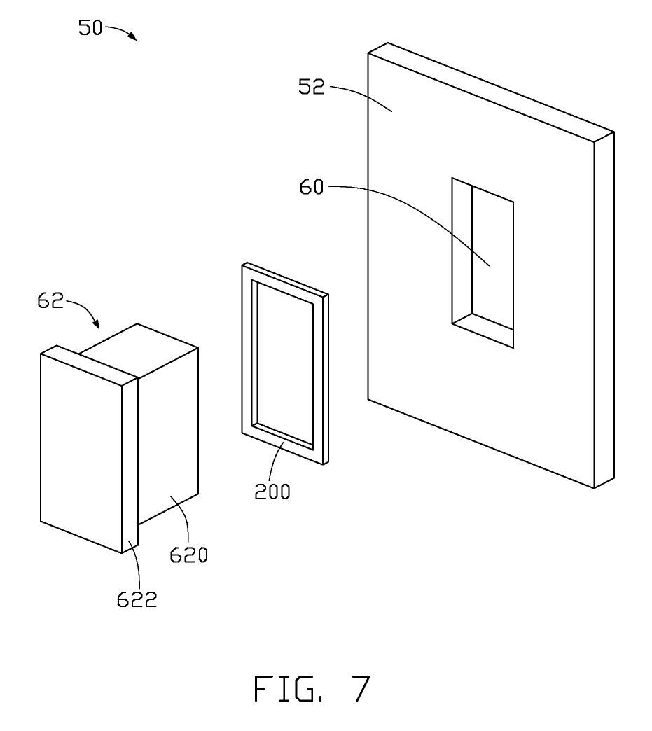

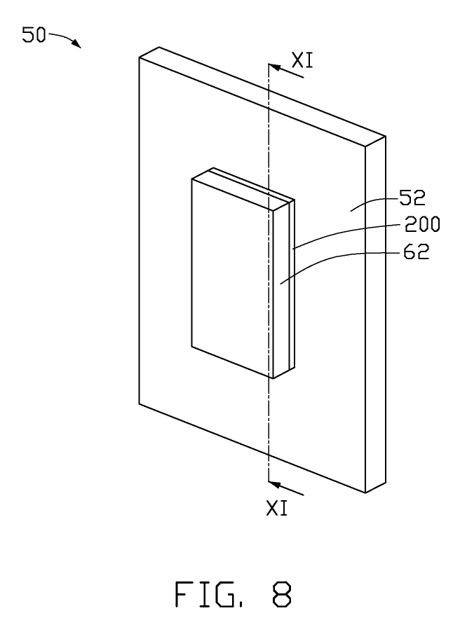

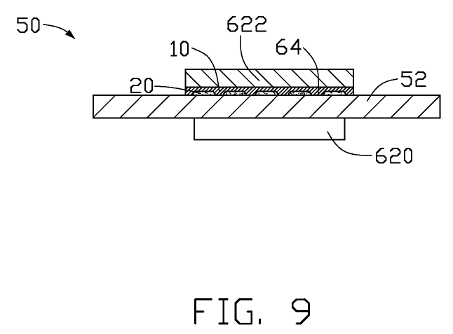

Furthermore, the notebook computer 50 also includes I/O ports to connect to other peripheral devices, such as keyboards, mice, printers, and so on. Referring to FIGS. 7-9, the notebook computer 50 defines an I/O port 60 therein without showing detailed structure of the I/O port 60. The I/O port 60 is configured for receiving connectors, such as RS232 connector, USB connector, and so on. In the embodiment, a connector 62 is configured for cooperatively establishing an electrical connection with the I/O port 60. The electromagnetic shield 200 is disposed between the I/O port 60 and the connector 62.

The I/O port 60 defines a receiving hole therein, and correspondingly the electromagnetic shield 200 also defines a through hole therein. The connector 62 includes a base 622 and a connection portion 620 formed on a side of the base 622. Herein, the connector 62 is shown for illustrative purposes but can also be connected to other peripheral devices, such as printers, scanners, and so on, via an electric wire.

In assembly, the electromagnetic shield 200 is attached to peripheral edges of the I/O port 60. The adhesive tapes 20 attaches to the peripheral edges. The connection portion 620 passes through the through hole of the electromagnetic shield 200, and is received in the receiving hole of the I/O port 60. The base 622 presses the electromagnetic shield 200 toward the I/O port 60. The conductive foam 10 partially deforms and fills the gaps 30 between the adhesive tapes 20, thereby, the conductive foam 10 is in direct contact with the peripheral edges of the I/O port 60. Therefore, the electromagnetic shield 200 can block electromagnetic energy from entering into the notebook computer 50 through the I/O port 60.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electromagnetic shield comprising:
a conductive foam; and
a plurality of adhesive tapes attached to a side of the conductive foam;
wherein the adhesive tapes are separated from each other.

2. The electromagnetic shield according to claim 1, wherein the adhesive tapes are aligned and separated from each other at a uniform distance.

3. The electromagnetic shield according to claim 1, wherein the adhesive tapes are aligned and separated from each other at various distances.

4. The electromagnetic shield according to claim 1, wherein the adhesive tapes are vertically aligned on the conductive foam with respect to an edge of the conductive foam.

5. The electromagnetic shield according to claim 1, wherein the adhesive tapes are obliquely aligned on the conductive foam with respect to an edge of the conductive foam.

6. The electromagnetic shield according to claim 1, wherein the conductive foam comprises a foam packed in a conductive coat.

7. The electromagnetic shield according to claim 6, wherein the conductive coat is made of metallic foils.

8. The electromagnetic shield according to claim 1, wherein each adhesive tape comprises a bond body and metallic grains dispersed in the bond body.

9. An electronic device comprising:
a housing;
an inner conductive component received in the housing; and
an electromagnetic shield disposed between the housing and the inner conductive component, the electromagnetic shield comprising:
a conductive foam;
a plurality of adhesive tapes attached to a side of the conductive foam;
wherein the adhesive tapes are separated from each other, and the conductive foam partially deforms and fills gaps between the adhesive tapes, thereby, the conductive foam is in direct contact with the housing.

10. The electronic device according to claim 9, wherein the adhesive tapes are aligned and separated from each other at a uniform distance.

11. The electronic device according to claim 9, wherein the adhesive tapes are aligned and separated from each other at various distances.

12. The electronic device according to claim 9, wherein each adhesive tape comprises a bond body and metallic grains dispersed in the bond body.

13. The electronic device according to claim 9, wherein the conductive foam comprises a foam packed in a conductive coat.

14. The electronic device according to claim 13, wherein the conductive coat is made of metallic foils.

15. An electronic device comprising:
a housing comprising an I/O port for receiving an outer conductive component;
an electromagnetic shield attached to peripheral edges of the I/O port, and for being disposed between the I/O port and the outer conductive component, the electromagnetic shield comprising:
a conductive foam;
a plurality of adhesive tapes attached to one side of the conductive foam;
wherein the adhesive tapes are separated from each other, and the conductive foam partially deforms and fills gaps between the adhesive tapes, thereby, the conductive foam is in direct contact with the peripheral edges of the I/O port.

16. The electronic device according to claim 15, wherein the adhesive tapes are aligned and separated from each other at a uniform distance.

17. The electronic device according to claim 15, wherein the adhesive tapes are aligned and separated from each other at various distances.

18. The electronic device according to claim 15, wherein each adhesive tape comprises a bond body and metallic grains dispersed in the bond body.

19. The electronic device according to claim 15, wherein the conductive foam comprises a foam packed in a conductive coat.

20. The electronic device according to claim 19, wherein the conductive coat is made of metallic foils.
